(19) United States
(12) Patent Application Publication
(10) Pub. No.: US 2025/0031518 A1
(43) Pub. Date: Jan. 23, 2025

(54) MANUFACTURING METHOD OF DISPLAY DEVICE

(71) Applicant: Samsung Display Co., LTD., Yongin-si (KR)

(72) Inventor: BOGEON JEON, Yongin-si (KR)

(21) Appl. No.: 18/626,500

(22) Filed: Apr. 4, 2024

(30) Foreign Application Priority Data
Jul. 19, 2023 (KR) 10-2023-0093671

(51) Int. Cl. H10K 59/12; H10K 59/18; H10K 71/60; H10K 71/80; H10K 77/10

(52) U.S. Cl. CPC H10K 59/1201; H10K 59/18; H10K 71/60; H10K 71/80; H10K 77/111

(57) ABSTRACT

A manufacturing method of a display device includes preparing a substrate including a metal pattern, forming a first active pattern disposed on the substrate and including first and second areas and a first channel area between the first and second areas, forming a first gate electrode pattern on the first active pattern, forming a second active pattern on the first gate electrode pattern, forming an etch stop pattern overlapping the first and second areas, forming an inter-insulating layer covering the etch stop pattern, defining a first hole exposing the etch stop pattern and a second hole exposing the inter-insulating layer, defining a third hole exposing a top surface of the substrate, defining a fourth hole penetrating the etch stop pattern and a fifth hole exposing the metal pattern, forming a metal pattern connection electrode on the metal pattern, and forming a light-emitting device on the metal pattern connection electrode.

This application claims priority to Korean Patent Application No. 10-2023-0093671, filed on Jul. 19, 2023, and all the benefits accruing therefrom under 35 U.S.C. § 119, the content of which in its entirety is herein incorporated by reference.

### BACKGROUND

### 1. Field

The disclosure relates to a manufacturing method of a display device. More specifically, the disclosure relates to a manufacturing method of a tiled display device.

### 2. Description of the Related Art

Generally, a tiled display device includes a plurality of display devices to implement a large screen. The plurality of display devices may be connected to each other in a structure of the tiled display device.

Each of the plurality of display devices may include a display area and a non-display area adjacent to the display area. An image may be displayed in the display area, and a driving circuit module (e.g., a driver integrated chip, a printed circuit board, or the like) for displaying the image may be disposed in the non-display area. That is, the non-display area may refer to a bezel with a predetermined width on which the driving circuit module for displaying the image is disposed.

### SUMMARY

Embodiments provide a manufacturing method of a display device with improved manufacturing process efficiency.

Embodiments provide a display device manufactured by the display device manufacturing method.

A manufacturing method of a display device in an embodiment includes preparing a substrate which includes a metal pattern and in which a display area and a non-display area are defined, forming a first active pattern disposed on the substrate and including a first area, a second area, and a first channel area disposed between the first area and the second area, forming a first gate electrode pattern overlapping the first channel area on the first active pattern, forming a second active pattern on the first gate electrode pattern, forming an etch stop pattern in a same layer as the second active pattern and overlapping the first area and the second area of the first active pattern, forming an inter-insulating layer covering the etch stop pattern, defining a first hole exposing the etch stop pattern and a second hole exposing the inter-insulating layer, defining a third hole extended to the second hole and exposing a top surface of the substrate, defining a fourth hole extended to the first hole and penetrating the etch stop pattern and a fifth hole extended to the third hole and exposing the metal pattern, forming a metal pattern connection electrode disposed on the metal pattern and connected to the metal pattern through the fifth hole, and forming a light-emitting device on the metal pattern connection electrode.

In an embodiment, the forming the substrate may further include forming a first base substrate on a carrier substrate, forming the metal pattern on the first base substrate, and forming a second base substrate on the first base substrate and the metal pattern.

In an embodiment, the third hole may expose a top surface of the second base substrate.

In an embodiment, the first base substrate and the second base substrate may include plastic with flexible characteristics.

In an embodiment, the first base substrate and the second base substrate may include polyimide.

In an embodiment, the method may further include removing the carrier substrate after the forming the light-emitting device.

In an embodiment, the method may further include forming a first insulating layer covering the first active pattern after the forming the first active pattern, and forming a second insulating layer covering the first gate electrode pattern after the forming the first gate electrode pattern.

In an embodiment, an etch rate of the first insulating layer, an etch rate of the second insulating layer, and an etch rate of the inter-insulating layer may be smaller than an etch rate of the etch stop pattern.

In an embodiment, when each of the first insulating layer, the second insulating layer, and the inter-insulating layer includes an inorganic material, an etch selectivity between at least one of the first insulating layer, the second insulating layer and the inter-insulating layer including the inorganic material and the etch stop pattern may be about 1:15 or more.

In an embodiment, when each of the first insulating layer, the second insulating layer, and the inter-insulating layer includes an organic material, an etch selectivity between at least one of the first insulating layer, the second insulating layer and the inter-insulating layers including the organic material and the etch stop pattern may be about 1:1000 or more.

In an embodiment, the first active pattern and the second active pattern may include different materials from each other.

In an embodiment, the first active pattern may include a silicon semiconductor.

In an embodiment, the etch stop pattern and the second active pattern may be formed simultaneously.

In an embodiment, the etch stop pattern and the second active pattern may include or consist of a same oxide semiconductor.

In an embodiment, the etch stop pattern and the second active pattern may include or consist of indium-gallium-zinc-oxide (“IGZO”).

In an embodiment, the fifth hole may be defined in the display area.

In an embodiment, the fifth hole may be defined in the non-display area.

The manufacturing method of the display device in an embodiment may include preparing a substrate which includes a metal pattern and in which a display area and a non-display area are defined, forming a first active pattern disposed on the substrate and including a first area, a second area, and a first channel area disposed between the first area and the second area, forming a first gate electrode pattern overlapping the first channel area on the first active pattern, forming a second active pattern on the first gate electrode pattern, forming an etch stop pattern in a same layer as the second active pattern and overlapping the first area and the second area of the first active pattern, forming an inter-insulating layer covering the etch stop pattern, defining a first hole exposing the etch stop pattern and a second hole exposing the inter-insulating layer, defining a third hole extended to the second hole and exposing a top surface of the substrate, defining a fourth hole extended to the first hole and penetrating the etch stop pattern and a fifth hole extended to the third hole and exposing the metal pattern, forming a metal pattern connection electrode disposed on the metal pattern and connected to the metal pattern through the fifth hole, and forming a light-emitting device on the metal pattern connection electrode. Accordingly, a photo process may be omitted once.

### BRIEF DESCRIPTION OF THE DRAWINGS

Illustrative, non-limiting embodiments will be more clearly understood from the following detailed description taken in conjunction with the accompanying drawings.

FIG. 1 is a perspective view illustrating an embodiment of a tiled display device according to the disclosure.

FIG. 2 is a front view of the tiled display device of FIG. 1.

FIG. 3 is a perspective view of the display device included in the tiled display device of FIG. 1.

FIG. 4 is a cross-sectional view taken along line I-I′ of FIG. 3.

FIG. 5 is a cross-sectional view taken along line II-II′ of FIG. 3.

FIGS. 6 to 21 are cross-sectional views illustrating the manufacturing method of the display device of FIG. 1.

### DETAILED DESCRIPTION

Embodiments of the disclosure now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

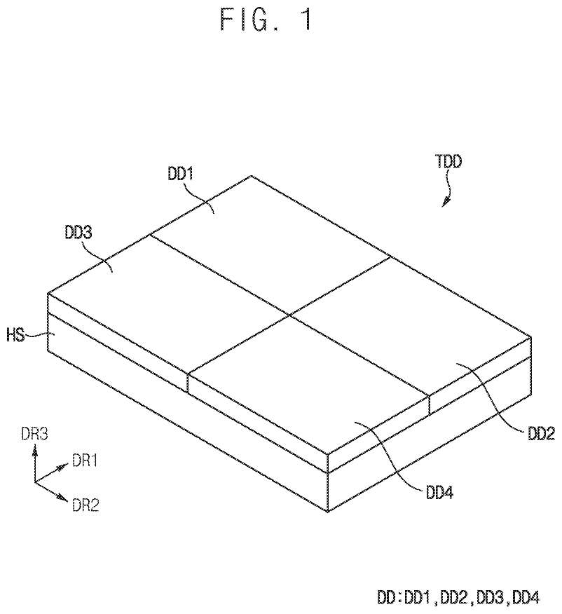

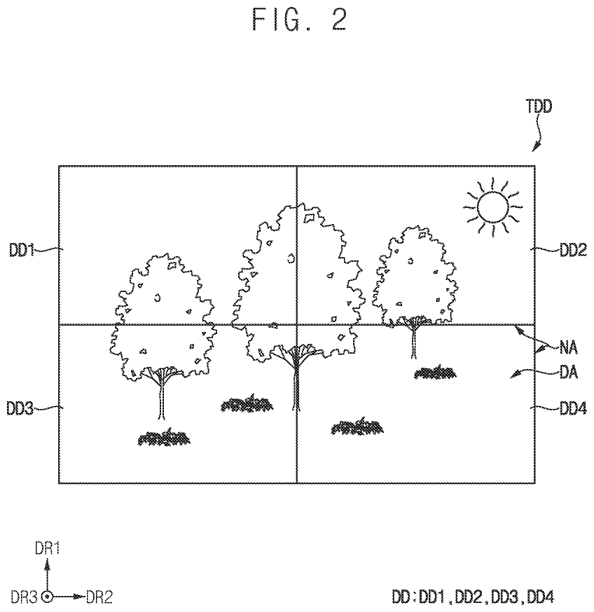

FIG. 1 is a perspective view illustrating a tiled display device according to the disclosure. FIG. 2 is a front view of the tiled display device of FIG. 1.

In an embodiment, the front view of FIG. 2 shows a front surface of a tiled display device TDD, for example. The front surface may be defined by a first direction DR1 and a second direction DR2. The second direction DR2 may cross the first direction DR1. The front surface is also referred to as “a display surface”.

Referring to FIGS. 1 and 2, the tiled display device TDD may include a plurality of display devices DD and a housing HS. The plurality of display devices DD may be arranged in a matrix form. Tiled display devices TDD are also referred to as “a multi-screen display”.

The tiled display device TDD may have various planar shapes. In an embodiment, the tiled display device TDD may have a quadrangular shape, e.g., rectangular shape, for example. However, the disclosure is not limited thereto. In an embodiment, the tiled display device TDD may have various shapes, such as circular or oval, for example. In addition, an edge of the tiled display device TDD may have an angular shape or a curved shape.

In an embodiment, the tiled display device TDD may be a rigid display device. In another embodiment, the tiled display device TDD may be a flexible display device, for example. In an embodiment, at least one area of the tiled display device TDD may be deformable, for example. Specifically, the tiled display device TDD may be folded, curved, or curved. However, the disclosure is not limited thereto.

The plurality of display devices DD may include a first display device DD1, a second display device DD2, a third display device DD3, and a fourth display device DD4. In an embodiment, as shown in FIG. 2, the plurality of display devices DD may divide and display one image, for example. In another embodiment, each of the plurality of display devices DD may individually display the image.

The housing HS may physically combine the plurality of display devices DD to form one tiled display device TDD. To this end, a fastening member, or the like may be further included between the housing HS and the plurality of display devices DD. In an embodiment, the housing HS may be disposed on a rear surface of the tiled display device TDD, for example. The rear surface may face the front surface in a third direction DR3. The third direction DR3 may cross the first direction DR1. In addition, the third direction DR3 may also cross the second direction DR2.

FIGS. 1 and 2 show the plurality of display devices DD arranged in two rows and two columns, however the disclosure is not limited thereto. In an embodiment, L number of display devices DD may be provided (where the L is a natural number of 2 or more), for example. In addition, the plurality of display device DD may be arranged in n rows and m columns (each of the n and the m is a natural number of 3 or more).

In addition, in FIGS. 1 and 2, the tiled display device TDD is described as including a plurality of display devices DD having a same size as each other, however the disclosure is not limited thereto. In an embodiment, the tiled display device TDD may include the plurality of display devices DD of various types, structures, sizes, and/or methods, for example.

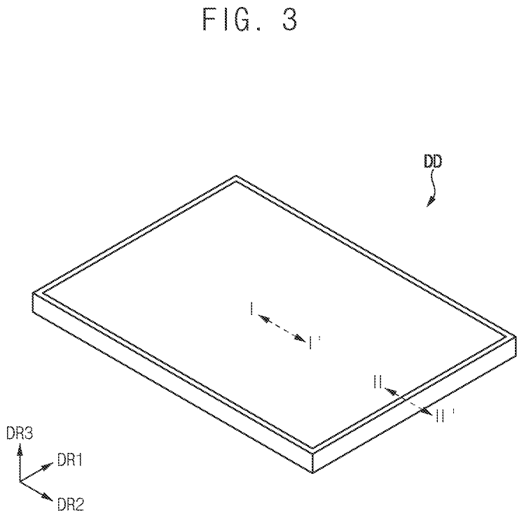

FIG. 3 is a perspective view of the display device included in the tiled display device of FIG. 1.

In an embodiment, one of the plurality of display devices DD may be the first display device DD1 included in the tiled display device TDD of FIG. 1, for example.

Referring to FIGS. 1, 2, and 3, each of the plurality of display devices DD may have various planar shapes. In an embodiment, each of the plurality of display devices DD may have a quadrangular shape, e.g., rectangular shape. However, the disclosure is not limited thereto. In an embodiment, each of the plurality of display devices DD may have various shapes, such as circular or oval. In addition, an edge of each of the plurality of display devices DD may have an angular shape or a curved shape.

In an embodiment, each of the plurality of display devices DD may be a rigid display device, for example. In another embodiment, each of the plurality of display devices DD may be a flexible display device. In an embodiment, at least one area of the plurality of display devices DD may be deformable, for example. Specifically, each of the plurality of display devices DD may be folded, curved, or curved. However, the disclosure is not limited thereto.

Each of the plurality of display devices DD may include a display area DA and a non-display area NA.

Each of the plurality of display devices DD may be an area that displays an image. To this end, pixels may be arranged in the display area DA. In an embodiment, each of the plurality of display devices DD may be an organic light-emitting display device including an organic light-emitting diode, for example. However, the disclosure is not limited thereto. In an embodiment, each of the plurality of display devices DD may be a liquid crystal display device including a liquid crystal capacitor, for example.

The display area DA may have various planar shapes. In an embodiment, the display area DA may have various planar shapes, such as quadrangular (e.g., rectangular), circular, or oval. However, the disclosure is not limited thereto.

The pixels may be arranged in the display area DA according to various arrangement structures. In an embodiment, the pixels may be arranged to be spaced apart from each other along the first direction DR1, for example. In an alternative embodiment, the pixels may be arranged to be spaced apart from each other along the second direction DR2. However, the disclosure is not limited thereto.

The display area DA may be defined on at least one side of each of the plurality of display devices DD. In an embodiment, the display area DA may be defined on the front surface of each of the plurality of display devices DD, for example. In an alternative embodiment, the display area DA may be defined on the rear or a side of each of the plurality of display devices DD. The side may cross the front (or the rear). The side surface may be defined by the first direction DR1 and the third direction DR3. In an alternative embodiment, the side surface may be defined by the second direction DR2 and the third direction DR3. However, the disclosure is not limited thereto.

The non-display area NA may be an area that does not display the image. That is, the pixel may not be disposed in the non-display area NA. A circuit structure (e.g., a line, a pad, a driving circuit, or the like) for driving the pixel may be disposed in the non-display area NA. The non-display area NA may include a black ink layer so that the circuit structure is not visible from an outside of each of the plurality of display devices DD. For this reason, the non-display area NA is also referred to as the bezel area. However, the disclosure is not limited thereto. In an embodiment, the ink layer may be omitted, and the circuit structure may be disposed in a different location, for example.

The non-display area NA may be adjacent to the display area DA. In an embodiment, the non-display area NA may surround the display area DA, for example. However, the disclosure is not limited thereto. In an embodiment, the non-display area NA may be disposed only on one side of the display area DA, for example.

When an area of the non-display area NA becomes small, a size of the display area DA may increase without increase a size of each of the plurality of display devices DD (or an area of each of the plurality of display devices DD. Through this, an area of the display surface on which the image is displayed may be increased.

In addition, when the area of the non-display area NA becomes small, when implementing the tiled display using the plurality of display devices DD, visibility of a boundary (or a seam) between the plurality of display devices DD may be reduced. Through this, a sense of disconnection in the image is alleviated and the image may be viewed more naturally.

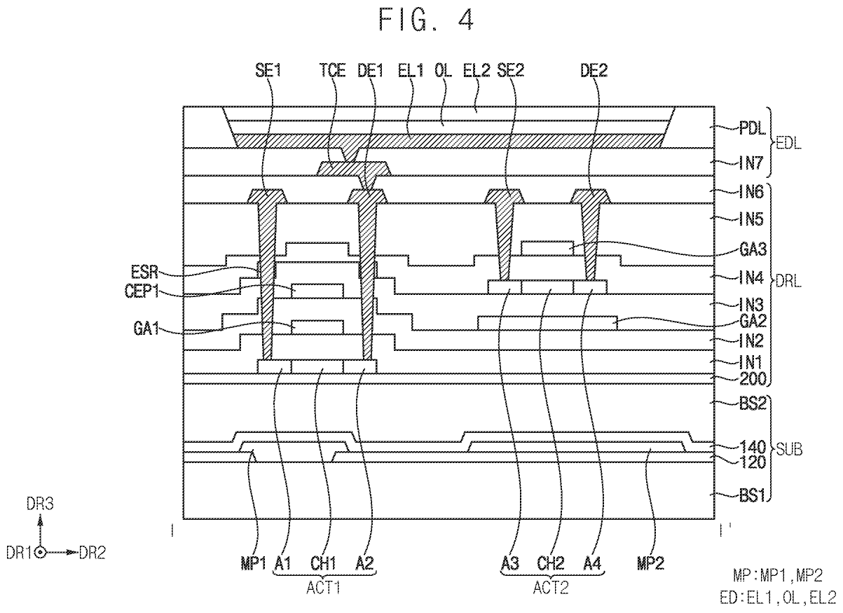

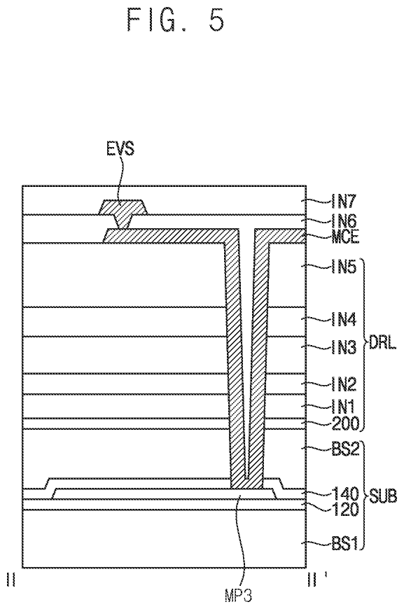

FIG. 4 is a cross-sectional view taken along line I-I′ of FIG. 3. FIG. 5 is a cross-sectional view taken along line II-II′ of FIG. 3.

Referring to FIGS. 3, 4, and 5, each of the plurality of display devices DD may include a substrate SUB, a device wiring layer DRL including at least one transistor, and a light-emitting device layer EDL.

In an embodiment, the device wiring layer DRL may be disposed on the substrate SUB. The light-emitting device layer EDL may be included and disposed on the device wiring layer DRL, for example. Although not shown in FIG. 4, when the device wiring layer DRL includes an organic material, the display device DD may further include an encapsulation layer to prevent oxidation of the organic material.

The substrate SUB may have flexible characteristics. In an embodiment, the substrate SUB may include a polymer organic material, plastic, or the like, for example.

The circuit structure connected to the pixel may be disposed on the device wiring layer DRL. In an embodiment, the device wiring layer DRL may include various lines, such as a gate line, a data line, a power line, or the like, for example. In an alternative embodiment, the device wiring layer DRL may further include a control line, or the like.

The light-emitting device layer EDL may include a light-emitting device constituting the pixel. There is no limitation on a type, a structure, a shape, a size, or the like of the light-emitting device included in the light-emitting device layer EDL.

In an embodiment, the substrate SUB may have a metal-embedded polyimide (“MEP”) structure including at least one metal pattern. In an embodiment, the substrate SUB may include a first base substrate BS1, a metal pattern MP, and a second base substrate BS2, for example.

Each of the first base substrate BS1 and the second base substrate BS2 may include plastic having the flexible properties. In an embodiment, each of the first base substrate BS1 and the second base substrate BS2 may include polyethersulphone (“PES”), polyacrylate (“PA”), polyetherimide (“PEI”), polyethylene naphthalate (“PEN”), polyethylene terephthalate (“PET”), polyphenylene sulfide (“PPS”), polyarylate (“PAR”), polyimide (“PI”), polycarbonate (“PC”), cellulose tri acetate (“TAC”), cellulose acetate propionate (“CAP”), or the like, for example. These may be used alone or in any combinations with each other. However, the disclosure is not limited thereto.

In an embodiment, each of the first base substrate BS1 and the second base substrate BS2 may include polyimide. However, the disclosure is not limited thereto. In an embodiment, each of the first base substrate BS1 and the second base substrate BS2 may include another polymer material, and each of the first base substrate BS1 and the second base substrate BS2 may include different polymer materials from each other, for example.

In an embodiment, the metal pattern MP may be disposed between the first base substrate BS1 and the second base substrate BS2. In an embodiment, the metal pattern MP may be disposed on the first base substrate BS1, and the second base substrate BS2 may be disposed on the first base substrate BS1 and the metal pattern MP, for example.

In an embodiment, the metal pattern MP may include a first metal pattern MP1, a second metal pattern MP2, and a third metal pattern MP3. In an embodiment, the metal pattern MP may be formed in the display area or the non-display area, for example. In an embodiment, as shown in FIG. 4, the first metal pattern MP1 and the second metal pattern MP2 may be formed in the display area, for example. In another embodiment, as shown in FIG. 5, the third metal pattern MP3 may be formed in the non-display area.

In an embodiment, a constant voltage may be provided to the metal pattern MP, for example. In an embodiment, the metal pattern MP may be connected to a voltage electrode pattern (a voltage electrode pattern EVS of FIG. 5), and a power supply voltage may be provided to the metal pattern MP, for example. However, the disclosure is not limited thereto. In an embodiment, an alternating voltage may be provided to the metal pattern MP, for example.

In an embodiment, the metal pattern MP may include a conductive metal or an alloy of the metal. In an embodiment, the metal pattern MP may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), copper (Cu), or the like, for example. These may be used alone or in any combinations with each other. However, the disclosure is not limited thereto. The metal pattern MP may be formed as a single layer or multiple layers.

The substrate SUB may further include at least one buffer layer. In an embodiment, a first buffer layer 120 may be disposed on the first base substrate BS1, for example. The metal pattern MP may be disposed on the first buffer layer 120. A second buffer layer 140 may be disposed on the first buffer layer 120 and the metal pattern MP. In addition, the second base substrate BS2 may be disposed on the second buffer layer 140

In an embodiment, each of the first buffer layer 120 and the second buffer layer 140 may include an inorganic material, for example. In an embodiment, each of the first buffer layer 120 and the second buffer layer 140 may include silicon nitride (SiNₓ), silicon oxide (SiOₓ), silicon oxynitride (SiOₓN_{y}), or the like, for example. These may be used alone or in any combinations with each other. However, the disclosure is not limited thereto.

In FIG. 4, the substrate SUB is described as including the first base substrate BS1 and the second base substrate BS2, however the disclosure is not limited thereto. In an embodiment, one of the first base substrate BS1 and the second base substrate BS2 may be omitted, for example.

In an embodiment, the device wiring layer DRL may be disposed on the substrate SUB. The device wiring layer DRL may include a first transistor, a second transistor, a first capacitor, a second capacitor, and an etch stop pattern residue ESR. In an embodiment, the first transistor may include a first active pattern ACT1 and a first gate electrode pattern GA1, for example. The first capacitor may include a first capacitor electrode pattern CEP1 that overlaps the first gate electrode pattern GA1. The second transistor may include a second gate electrode pattern GA2 and a second active pattern ACT2. The second capacitor may include a second capacitor electrode pattern that overlaps a portion of the second active pattern ACT2.

A third buffer layer 200 may be disposed on the substrate SUB. In an embodiment, the third buffer layer 200 may be disposed on the second base substrate BS2, for example.

The third buffer layer 200 may prevent impurities from penetrating into the transistor (e.g., the first transistor and/or the second transistor). In addition, the third buffer layer 200 may control a rate at which heat is provided during a crystallization process to form the first active pattern ACT1. Accordingly, the first active pattern ACT1 may be formed uniformly.

In an embodiment, the third buffer layer 200 may include an inorganic insulating material, for example. In an embodiment, the inorganic insulating material may include silicon nitride, silicon oxide, silicon oxynitride, or the like, for example. These may be used alone or in any combinations with each other. However, the disclosure is not limited thereto. In an embodiment, the third buffer layer 200 may include an organic material, for example. In an alternative embodiment, the third buffer layer 200 may be omitted.

In an embodiment, the first active pattern ACT1 may be disposed on the substrate SUB. In an embodiment, the first active pattern ACT1 may be disposed on the third buffer layer 200, for example.

In an embodiment, the first active pattern ACT1 may include a first area A1, a first channel area CH1, and a second area A2. The first area A1 and the second area A2 may be spaced apart from each other in the second direction DR2, for example. The first channel area CH1 may be disposed between the first area A1 and the second area A2.

In an embodiment, the first active pattern ACT1 may include a silicon semiconductor. In an embodiment, the silicon semiconductor may include amorphous silicon, polycrystalline silicon, or the like, for example. In an embodiment, the first active pattern ACT1 may include the polycrystalline silicon formed by crystallizing the amorphous silicon, for example. The crystallization may be performed at relatively low temperature.

The first active pattern ACT1 may be doped (e.g., implanted with ions). In an embodiment, when the first active pattern ACT1 constitutes a p-channel metal-oxide-semiconductor (“PMOS”) transistor, ions such as boron (B) may be implanted into the first active pattern ACT1, for example.

A first insulating layer IN1 may be disposed on the first active pattern ACT1. The first insulating layer IN1 may be disposed under the first gate electrode pattern GA1 and is also referred to as “a first gate insulating layer”.

In an embodiment, the first insulating layer IN1 may include an inorganic insulating material, for example. In an embodiment, the inorganic insulating material may include silicon oxide, silicon nitride, silicon oxy nitride, aluminum oxide, titanium oxide, tantalum oxide, hafnium oxide, or the like, for example. These may be used alone or in any combinations with each other. The first insulating layer IN1 may have a single-layer or multiple layers structure. However, the disclosure is not limited thereto. In an embodiment, the first insulating layer IN1 may include an organic material, for example.

In an embodiment, the first gate electrode pattern GA1 may be disposed on the first active pattern ACT1 to overlap the first channel area CH1.

In an embodiment, the first gate electrode pattern GA1 may include a conductive material, for example. In an embodiment, the first gate electrode pattern GA1 may include aluminum (Al), molybdenum (Mo), copper (Cu), titanium (Ti), or the like, for example. These may be used alone or in any combinations with each other. However, the disclosure is not limited thereto.

A second insulating layer IN2 may be disposed on the first gate electrode pattern GA1. The second insulating layer IN2 may be disposed under the second gate electrode pattern GA2 and is also referred to as “a second gate insulating layer”.

In an embodiment, the second insulating layer IN2 may include an inorganic insulating material, for example. In an embodiment, the inorganic insulating material may include silicon nitride (SiNₓ), silicon oxy nitride (SiOₓN_{y}), aluminum oxide (AlOₓ), or the like, for example. These may be used alone or in any combinations with each other. The second insulating layer IN2 may have a single-layer or multiple layers structure. However, the disclosure is not limited thereto. In an embodiment, the second insulating layer IN2 may include an organic material, for example.

In an embodiment, the first capacitor electrode pattern CEP1 may be disposed on the first gate electrode pattern GA1. The first capacitor electrode pattern CEP1 may form the storage capacitor with the first gate electrode pattern GA1. The first transistor (e.g., a driving transistor) may control a driving current flowing through a light-emitting device ED based on a stored voltage value.

In an embodiment, the first capacitor electrode pattern CEP1 may include a conductive material, for example. However, the disclosure is not limited thereto.

In an embodiment the first capacitor electrode pattern CEP1 may be disposed in a same layer as the second gate electrode pattern GA2.

In an embodiment, the second gate electrode pattern GA2 may include a conductive material, for example. However, the disclosure is not limited thereto. In an embodiment, the first capacitor electrode pattern CEP1 and the second gate electrode pattern GA2 may include a same material as each other. In an embodiment, the first capacitor electrode pattern CEP1 and the second gate electrode pattern GA2 may be formed simultaneously, for example. However, the disclosure is not limited thereto.

A third insulating layer IN3 may be disposed on the first capacitor electrode pattern CEP1 and the second gate electrode pattern GA2. The third insulating layer IN3 is also referred to as “a first inter-insulating layer.” The third insulating layer IN3 may be disposed under the second active pattern ACT2, which will be described later, and is also referred to as “an oxide buffer layer.” That is, the third insulating layer IN3 may prevent the impurities from penetrating into the second active pattern ACT2.

In an embodiment, the third insulating layer IN3 may include an inorganic insulating material, for example. In an embodiment, the inorganic insulating material may include silicon nitride (SiNₓ), silicon oxy nitride (SiOₓN_{y}), aluminum oxide (AlOₓ), or the like, for example. These may be used alone or in any combinations with each other. The third insulating layer IN3 may have a single-layer or multiple layers structure. However, the disclosure is not limited thereto. In an embodiment, the third insulating layer IN3 may include an organic material, for example.

In an embodiment, the second active pattern ACT2 may be disposed on the second gate electrode pattern GA2. In an embodiment, the second active pattern ACT2 may be disposed on the third insulating layer IN3, for example. Specifically, the second active pattern ACT2 may be disposed to be spaced apart from the first active pattern ACT1. In an embodiment, the second active pattern ACT2 may be disposed on the first insulating layer IN1 at a location spaced apart from the first active pattern ACT1 in the second direction DR2, for example.

In an embodiment, the second active pattern ACT2 may include a third area A3, a second channel area CH2, and a fourth area A4, for example. The third area A3 and the fourth area A4 may be spaced apart from each other in the second direction DR2. The second channel area CH2 may be disposed between the third area A3 and the fourth area A4.

In an embodiment, the first active pattern ACT1 and the second active pattern ACT2 may include different materials from each other. In an embodiment, in an embodiment, the second active pattern ACT2 may include an oxide semiconductor, for example. In an embodiment, the oxide semiconductor may include indium-gallium-zinc-oxide (“IGZO”), for example. However, the disclosure is not limited thereto. In an embodiment, the second active pattern ACT2 may include another semiconductor material or an oxide semiconductor other than IGZO, for example.

In an embodiment, the etch stop pattern residue ESR may be disposed in a same layer as the second active pattern ACT2. Specifically, the etch stop pattern residue ESR may be disposed to overlap the first area A1 and the second area A2 of the first active pattern ACT1.

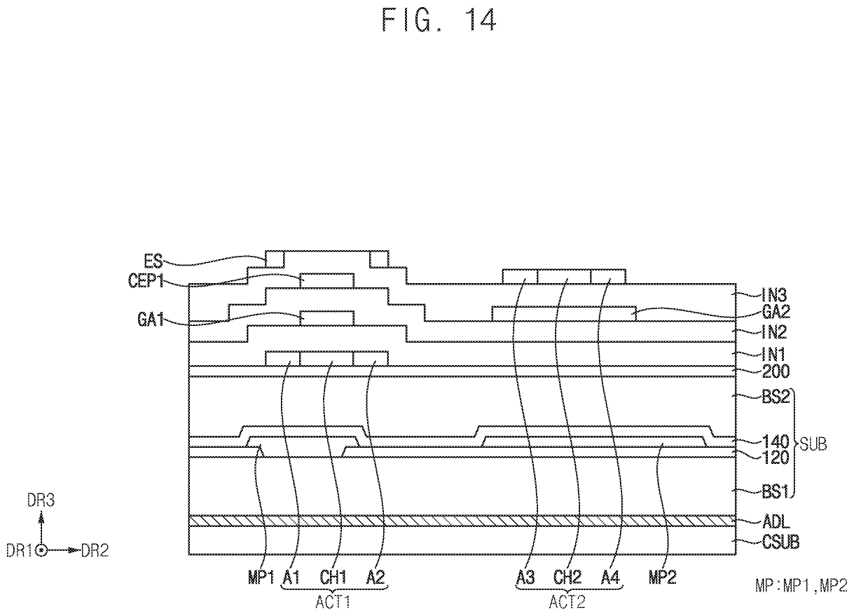

The etch stop pattern residue ESR may refer to a material remaining around a contact hole in a process of defining a contact hole penetrating an etch stop pattern (e.g., an etch stop pattern ES of FIG. 14).

In an embodiment, the second active pattern ACT2 and the etch stop pattern residue ESR may include a same oxide semiconductor. In an embodiment, the oxide semiconductor may include IGZO, for example. In an embodiment, the second active pattern ACT2 and the etch stop pattern residue ESR may be formed simultaneously, for example. However, the disclosure is not limited thereto.

A fourth insulating layer IN4 may be disposed on the second active pattern ACT2 and the etch stop pattern residue ESR. The fourth insulating layer IN4 is also referred to as “a third gate insulating layer”.

In an embodiment, the fourth insulating layer IN4 may include an inorganic insulating material, for example. In an embodiment, the inorganic insulating material may include silicon nitride (SiNₓ), silicon oxy nitride (SiOₓN_{y}), aluminum oxide (AlOₓ), or the like, for example. These may be used alone or in any combinations with each other. The fourth insulating layer IN4 may have a single-layer or multiple layers structure. However, the disclosure is not limited thereto. In an embodiment, the fourth insulating layer IN4 may include an organic material, for example.

In an embodiment, the third gate electrode pattern GA3 may be disposed on the second gate electrode pattern GA2, for example. In an embodiment, the third gate electrode pattern GA3 may be disposed on the fourth insulating layer IN4, for example.

In an embodiment, the third gate electrode pattern GA3 may include a conductive material, for example. However, the disclosure is not limited thereto.

In FIG. 4, the first transistor has a top gate structure and the second transistor has a dual gate structure, however the disclosure is not limited thereto.

A fifth insulating layer IN5 may be disposed on the second capacitor electrode pattern. The fifth insulating layer IN5 is also referred to as “a second inter-insulating layer”.

In an embodiment, the fifth insulating layer IN5 may include an inorganic insulating material, for example. In an embodiment, the inorganic insulating material may include silicon nitride (SiNₓ), silicon oxy nitride (SiOₓN_{y}), aluminum oxide (AlOₓ), or the like, for example. These may be used alone or in any combinations with each other. The fifth insulating layer IN5 may have a single-layer or multiple layers structure. However, the disclosure is not limited thereto. In an embodiment, the fifth insulating layer IN5 may include an organic material, for example.

A first source electrode SE1, a first drain electrode DE1, a second source electrode SE2, a second drain electrode DE2, and the metal pattern connection electrode MCE may be formed on the second active pattern ACT2. In an embodiment, the first source electrode SE1, the first drain electrode DE1, the second source electrode SE2, the second drain electrode DE2, and the metal pattern connection electrode MCE may be disposed on the fifth insulating layer IN5, for example.

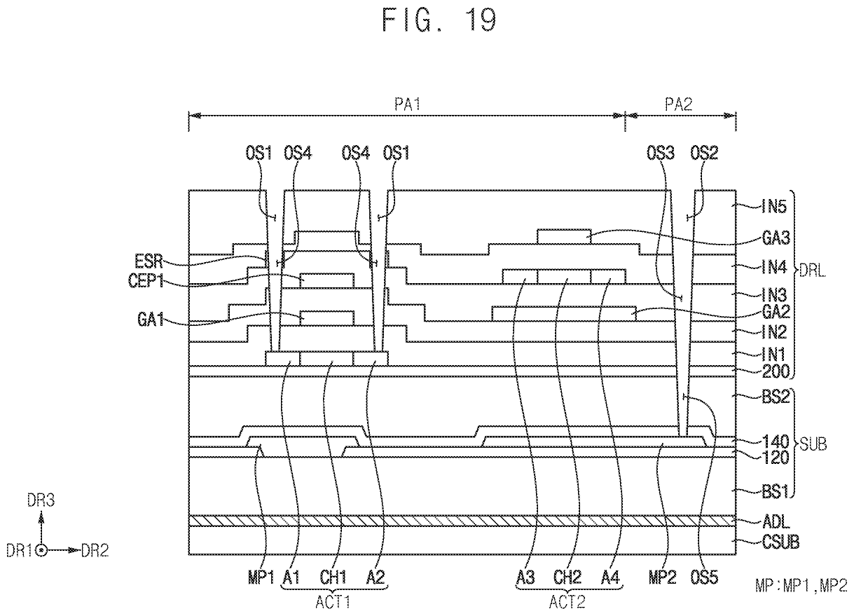

In an embodiment, each of the first source electrode SE1 and the first drain electrode DE1 may be connected to the first active pattern ACT1 through a first contact hole (e.g., a first hole OS1 and a fourth hole OS4 of FIG. 19), for example. In an embodiment, the first source electrode SE1 may be connected to the first area A1 of the first active pattern ACT1, for example. The first drain electrode DE1 may be connected to the second area A2 of the first active pattern ACT1.

In addition, each of the second source electrode SE2 and the second drain electrode DE2 may be connected to the second active pattern ACT2 through a second contact hole. In an embodiment, the second source electrode SE2 may be connected to the third area A3 of the second active pattern ACT2, for example. The second drain electrode DE2 may be connected to the fourth area A4 of the second active pattern ACT2.

In addition, the metal pattern connection electrode MCE may be connected to the metal pattern MP through a third contact hole (e.g., a second hole OS2, a third hole OS3, and a fifth hole OS5 of FIG. 19). Accordingly, a power voltage may be provided to the light-emitting device.

However, the disclosure is not limited thereto. In an embodiment, positions of the first source electrode SE1 and the first drain electrode DE1 may be changed, and positions of the second source electrode SE2 and the second drain electrode DE2 may also be changed, for example.

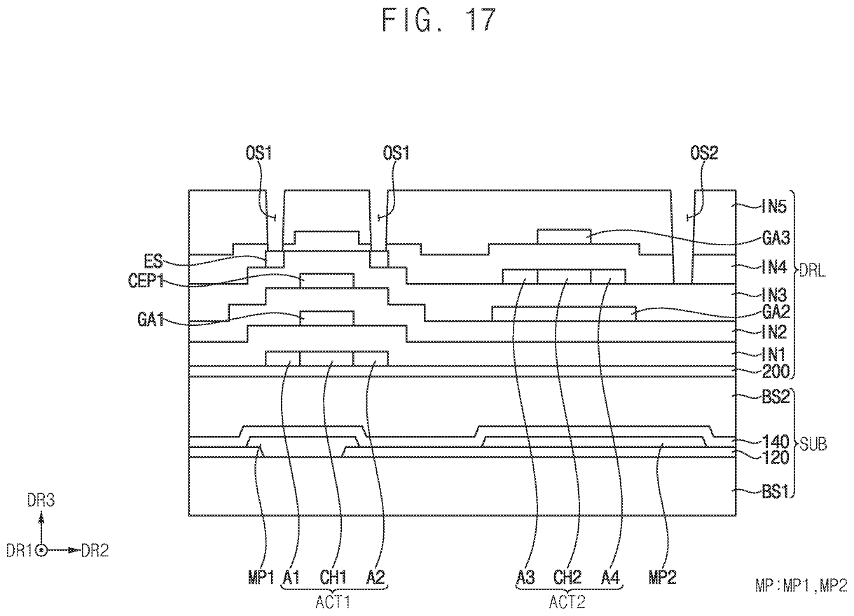

The first contact hole and the third contact hole may be formed simultaneously. For this purpose, in an embodiment, an etch rate of the first insulating layer IN1, an etch rate of the second insulating layer IN2, an etch rate of the third insulating layer IN3, an etch rate of the fourth insulating layer IN4, and an etch rate of the fifth insulating layer IN5 may be less than an etch rate of an etch stop pattern (e.g., an etch stop pattern ES of FIG. 17).

In an embodiment, when the first to fifth insulating layers IN1, IN2, IN3, IN4, and IN5 may include an inorganic material, an etch selectivity ratio between at least one of the first to fifth insulating layers IN1, IN2, IN3, IN4, and IN5 and the etch stop pattern may be about 1:15 or more.

In an embodiment, when the first to fifth insulating layers IN1, IN2, IN3, IN4, and IN5 may include an organic material, an etch selectivity ratio between at least one of the first to fifth insulating layers IN1, IN2, IN3, IN4, and IN5 and the etch stop pattern may be about 1:1000 or more.

After the etch stop pattern having the etch selectivity is disposed at a location where the first contact hole is to be formed, the first contact hole and the third contact hole may be formed. While loss occurs at the location where the first contact hole is formed, a deeper hole may be formed at the location where the third contact hole is formed.

A display device according to a comparative example might not include the etch stop pattern. Accordingly, the substrate SUB may be formed, the third contact hole may be formed (first contact hole forming process), the second active pattern ACT2 may be formed, the first contact hole and the third contact hole may be formed (secondary contact hole forming process), and the light-emitting device may be formed.

The display device in an embodiment of the disclosure may include the etch stop pattern. The etch stop pattern may control etching time. Accordingly, after forming the substrate SUB to the second active pattern ACT2, the first contact hole and the third contact hole may be formed simultaneously. That is, the first contact hole forming process may be omitted in the manufacturing process of the display device according to the comparative example. Accordingly, efficiency of the manufacturing process of the display device (e.g., one of the plurality of display devices DD of FIG. 3) may be improved.

In an embodiment, each of the first source electrode SE1, the first drain electrode DE1, the second source electrode SE2, the second drain electrode DE2, and the metal pattern connection electrode MCE may include a conductive metal, metal alloys, conductive metal oxides, transparent conductive materials, or the like, for example. However, the disclosure is not limited thereto.

In an embodiment, each of the first source electrode SE1, first drain electrode DE1, second source electrode SE2, and second drain electrode DE2 may have multiple layers structure, for example. In an embodiment, the multiple layers structure may include a first conductive layer including titanium, a second conductive layer including aluminum, and a third conductive layer including titanium, for example. However, the disclosure is not limited thereto.

A sixth insulating layer IN6 may be disposed on the first source electrode SE1, the second source electrode SE2, the first drain electrode DE1, the second drain electrode DE2, and the metal pattern connection electrode MCE. The sixth insulating layer IN6 may provide a flat top surface. The sixth insulating layer IN6 is also referred to as “a first planarization layer” or “a first via-insulating layer.”

In an embodiment, the sixth insulating layer IN6 may include an organic insulating material, for example. In an embodiment, the organic insulating material may include photoresist, polyacrylic resin, polyimide resin, acrylic resin, or the like, for example. These may be used alone or in any combinations with each other. The sixth insulating layer IN6 may have a single-layer or multiple layers structure. However, the disclosure is not limited thereto. In an embodiment, the sixth insulating layer IN6 may include an inorganic material, for example.

In an embodiment, the light-emitting device layer EDL may be disposed on the device wiring layer DRL. The light-emitting device layer EDL may include a connection electrode TCE and the light-emitting device ED.

The connection electrode TCE may be disposed on the first drain electrode DE1 (or the first source electrode SE1). The connection electrode TCE may contact the first drain electrode DE1 (or the first source electrode SE1).

In an embodiment, the connection electrode TCE may include a conductive metal, an alloy of the metal, a conductive metal oxide, a transparent conductive material, or the like, for example. However, the disclosure is not limited thereto. In an alternative embodiment, the connection electrode TCE may be omitted.

A seventh insulating layer IN7 may be disposed on the connection electrode TCE. The seventh insulating layer IN7 may provide a flat top surface. The seventh insulating layer IN7 may also be also referred to as “a second planarization layer” or “a second via-insulating layer.”

In an embodiment, the seventh insulating layer IN7 may include the organic insulating material, for example. However, the disclosure is not limited thereto. In an embodiment, the seventh insulating layer IN7 may include an inorganic material, for example.

In an embodiment, the light-emitting device ED may be disposed on the etch stop pattern residue ESR and the second active pattern ACT2. In an embodiment, the light-emitting device ED may be disposed on the seventh insulating layer IN7, for example. In an embodiment, the light-emitting device ED may include a first electrode EL1, a light-emitting material layer OL, and a second electrode EL2, for example.

The first electrode EL1 may be disposed on the seventh insulating layer IN7. In an embodiment, the first electrode EL1 may be an anode electrode, for example. In an embodiment, the first electrode EL1 may include conductive oxide, for example. The conductive oxide may include indium tin oxide, indium zinc oxide, zinc oxide, indium oxide, indium gallium oxide, aluminum zinc oxide, or the like. In another embodiment, the first electrode EL1 may include a highly reflective metal. The highly reflective metal may include silver (Ag), magnesium (Mg), aluminum (Al), platinum (Pt), palladium (Pd), gold (Au), nickel (Ni), neodymium (Nd), and iridium (Ir), chromium (Cr), or the like. These may be used alone or in any combinations with each other. However, the disclosure is not limited thereto.

A pixel defining layer PDL may be disposed on the first electrode EL1. The pixel defining layer PDL may define a pixel opening that exposes a portion of a top surface of the first electrode EL1. In an embodiment, the pixel defining layer PDL may include an insulating material, for example.

The light-emitting material layer OL may be disposed within the pixel opening defined by the pixel defining layer PDL. In an embodiment, the light-emitting material layer OL may include an organic light-emitting material, for example. The light-emitting material layer OL may further include one or more functional layers. The functional layer may be a layer that helps luminous efficiency of the light-emitting device ED.

The second electrode EL2 may be disposed on the light-emitting material layer OL. In an embodiment, the second electrode EL2 may be a cathode electrode. In an embodiment, the second electrode EL2 may include the highly reflective metal, for example. However, the disclosure is not limited thereto. Positions of the anode electrode and the cathode electrode may be changed. In an embodiment, the cathode electrode may include the conductive oxide, for example.

In the above description, each of the plurality of display devices DD includes an organic light-emitting device (hereinafter, also referred to as an organic light-emitting element) ED including the organic light-emitting material, however the disclosure is not limited thereto. In an embodiment, each of the display devices DD may be capable of self-emitting light, such as an organic light-emitting display panel using an organic light-emitting diode as a light-emitting element, a nano-scale led display panel using a nano-scale light-emitting diode as a light-emitting element, a quantum dot organic light-emitting display panel using an organic light-emitting diode and a quantum dot, a quantum dot nano-scale led display panel suing an ultra-small light-emitting diode and a quantum dot, or the like, for example.

In another embodiment, the plurality of display devices DD may be a non-luminous display device, such as a liquid crystal display panel, an electro-phoretic display panel, an electro-wetting display panel, or the like. In an embodiment, each of the plurality of display devices DD may further include a separate light source (e.g., a backlight unit), for example.

In addition, for convenience of explanation, only up to the light-emitting element ED is shown in FIG. 4 and only up to the metal pattern connection electrode MCE is shown in FIG. 5. However, each of the plurality of display devices DD in an embodiment of the disclosure may further include various layers, and the layers described above may be omitted.

In the above, only up to the metal pattern connection electrode MCE connected to the third metal pattern MP3 is shown, however the disclosure is not limited thereto. In an embodiment, the metal pattern connection electrode MCE may be disposed in the display area, for example.

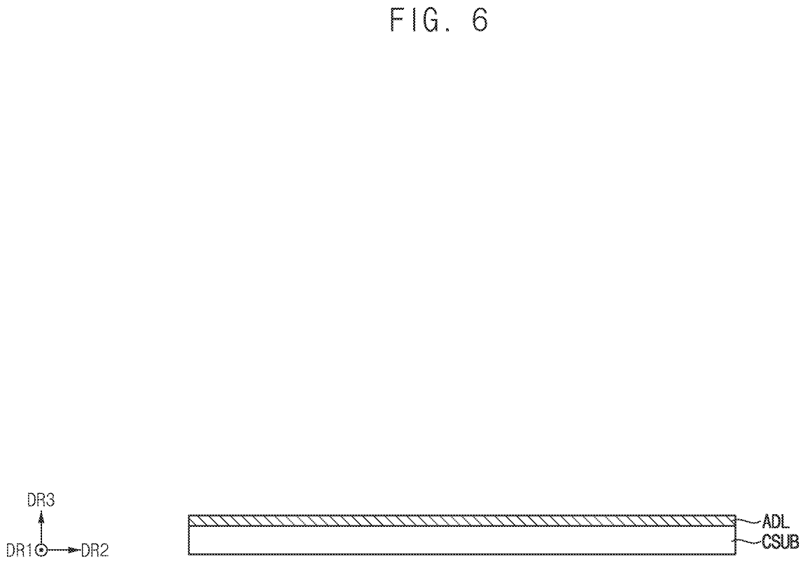

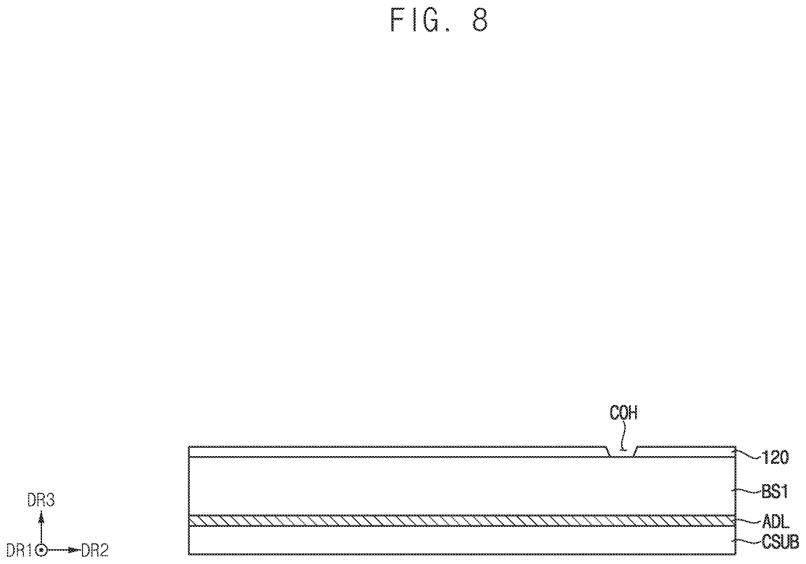

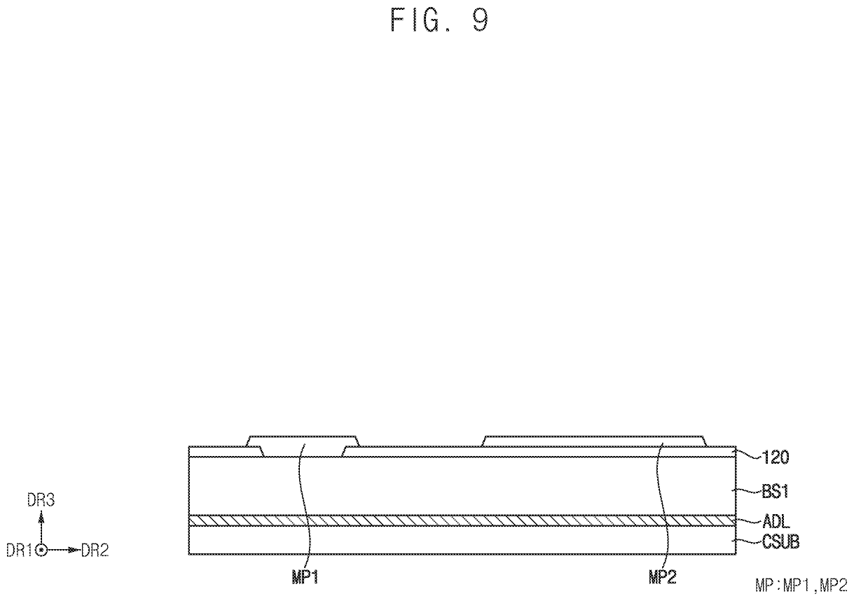

FIGS. 6 to 21 are cross-sectional views illustrating the manufacturing method of the display device of FIG. 1. Hereinafter, descriptions that overlap with the description of the tiled display device TDD described above with reference to FIGS. 1 to 5 will be omitted or simplified.

Referring to FIGS. 6, 7, 8, 9, and 10, in an embodiment, the substrate SUB including the metal pattern MP may be formed on a carrier substrate CSUB.

In an embodiment, the first base substrate BS1 may be formed on the carrier substrate CSUB. In an embodiment, the first base substrate BS1 may include or consist of a material with flexible characteristics. In an embodiment, in order to support the first base substrate BS1, the first base substrate BS1 may be formed on the carrier substrate CSUB having rigid characteristics, for example.

Before forming the first base substrate BS1, an auxiliary layer ADL may be formed on the carrier substrate CSUB. In an embodiment, the auxiliary layer ADL may include a material that is easily removed by a laser, for example. The auxiliary layer ADL may include a material that assists the carrier substrate CSUB to be easily separated from the substrate (e.g., the substrate SUB of FIG. 4) in a process of removing the carrier substrate CSUB after forming the light-emitting device (e.g., the light-emitting device ED of FIG. 4).

In an embodiment, the first base substrate BS1 may include or consist of plastic having the flexible properties. In an embodiment, the plastic may be polyimide, for example. In an embodiment, the first base substrate BS1 may be formed through a coating process, for example. However, the disclosure is not limited thereto.

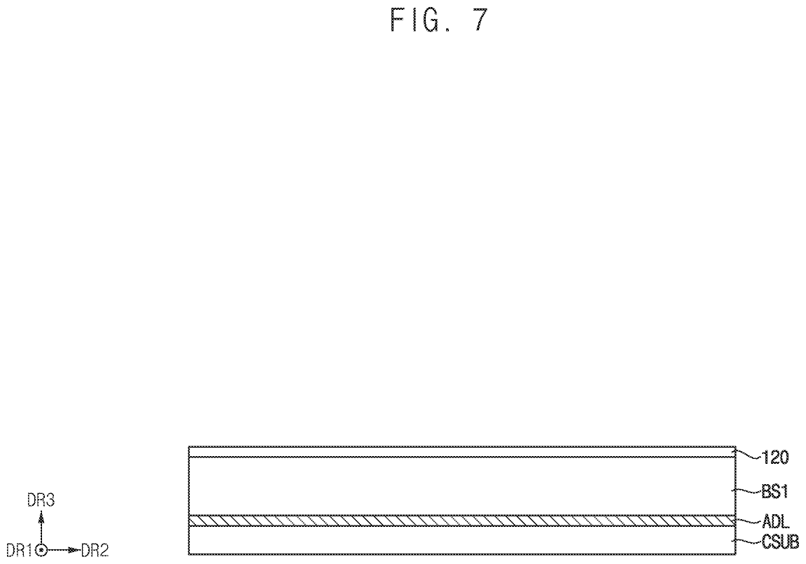

As shown in FIGS. 7, 8, and 9, in an embodiment, the metal pattern MP may be formed on the first base substrate BS1. In an embodiment, a first buffer layer 120 may be formed on the first base substrate BS1. A hole COH may be defined through the first buffer layer 120 to expose a portion of a top surface of the first base substrate BS1, for example. The metal pattern MP may be formed on the first buffer layer 120. At this time, the metal pattern MP may contact the first base substrate BS1 through the hole COH.

The metal pattern MP may include or consist of a conductive metal material. In an embodiment, the metal pattern MP may be formed through a photo process, for example. However, the disclosure is not limited thereto.

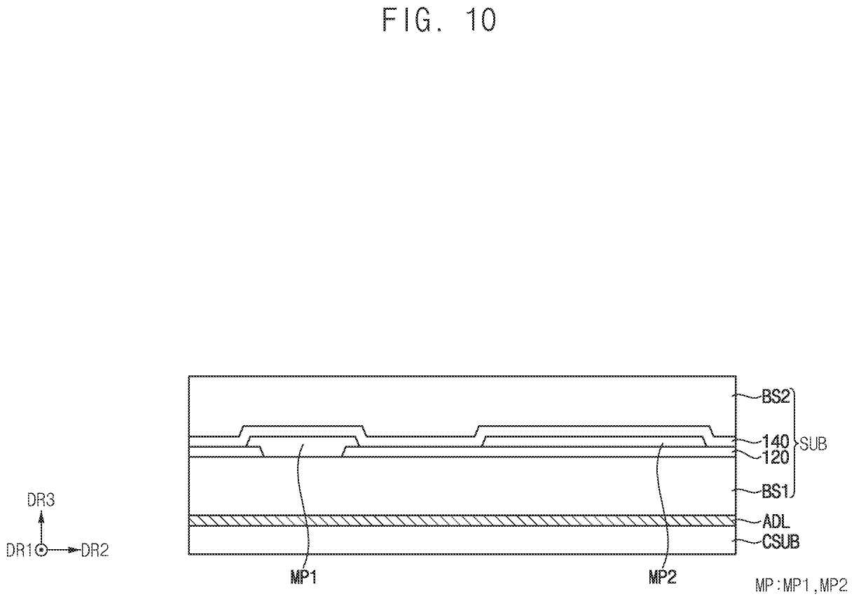

As shown in FIG. 10, in an embodiment, the second base substrate BS2 may be formed on the first base substrate BS1 and the metal pattern MP. Accordingly, the substrate SUB may be formed.

In an embodiment, the second base substrate BS2 may include or consist of plastic having the flexible characteristics. In an embodiment, the plastic may include polyimide, for example. In an embodiment, the second base substrate BS2 may be formed through the coating process, for example.

However, the disclosure is not limited thereto. In an embodiment, one of the first base substrate BS1 and the second base substrate BS2 may be omitted, for example.

In the manufacturing method of the display device according to the comparative example, the photo process may be performed after forming the substrate SUB. However, in the manufacturing method of the display device according to the disclosure, the photo process may be omitted after forming the substrate SUB by the etch stop pattern. A detailed description of the etch stop pattern (e.g., the etch stop pattern ES of FIG. 14) will be described later with reference to FIGS. 14 to 21. disclosure is not limited thereto.

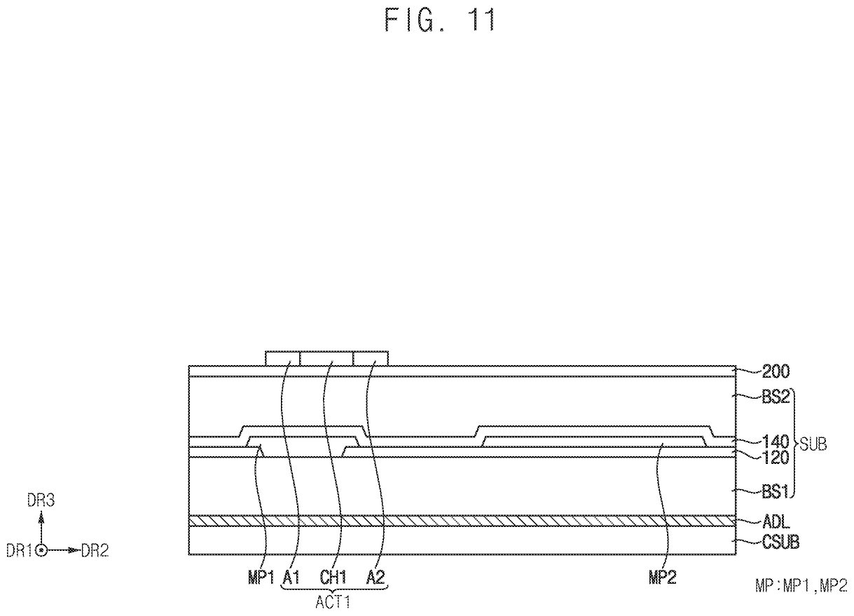

Referring to FIG. 11, in an embodiment, the first active pattern ACT1 may be formed on the substrate SUB.

In an embodiment, a third buffer layer 200 may be formed on the substrate SUB, for example. In an embodiment, the third buffer layer 200 may include or consist of an inorganic insulating material. In an embodiment, the third buffer layer 200 may be formed through a deposition process, for example. However, the disclosure is not limited thereto.

In an embodiment, the first active pattern ACT1 may be formed on the third buffer layer 200, for example. For convenience of explanation, in FIG. 11, the first active pattern ACT1 includes the first area A1, the second area A2, and the first channel area CH1 between the first area A1 and the second area A2, the first active pattern ACT1 may be doped using the first gate electrode pattern GA1, which will be described later, as a mask.

In an embodiment, the first active pattern ACT1 may include or consist of a silicon semiconductor, for example. In an embodiment, the first active pattern ACT1 may be formed by the deposition process (e.g., a chemical vapor deposition (“CVD”) process), the crystallization process (e.g., an excimer laser annealing (“ELA”) process) of the silicon semiconductor material, the photo process or the like, for example.

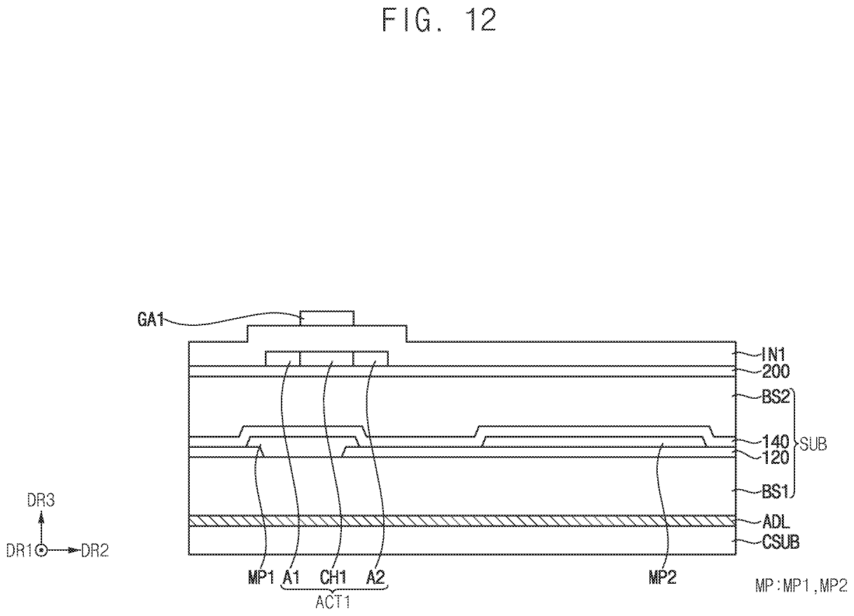

Referring to FIG. 12, in an embodiment, the first gate electrode pattern GA1 may be formed on the first active pattern ACT1.

The first insulating layer IN1 may be formed on the first active pattern ACT1. In an embodiment, the first insulating layer IN1 may include or consist of the inorganic insulating material, for example. In an embodiment, the first insulating layer IN1 may be formed by the deposition process, for example.

In an embodiment, the first gate electrode pattern GA1 may be formed on the first insulating layer IN1. The first gate electrode pattern GA1 may overlap the first channel area CH1.

In an embodiment, the first gate electrode pattern GA1 may include or consist of the metal material, for example. In an embodiment, the first gate electrode pattern GA may be formed by the deposition process (e.g., sputter process) and the photo process, for example.

Afterwards, a doping process to form the first active pattern ACT1 may be performed. Accordingly, the first channel area CH1 of the first active pattern ACT1 and the first gate electrode pattern GA1 may overlap each other. However, the disclosure is not limited thereto.

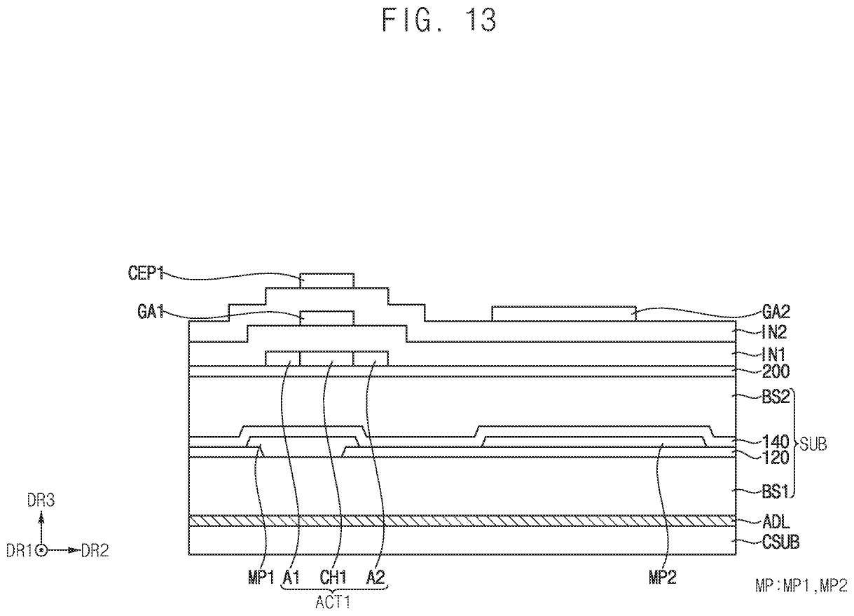

Referring to FIG. 13, the second gate electrode pattern GA2 and the first capacitor electrode pattern CEP1 may be formed on the first gate electrode pattern GA1.

In an embodiment, the second insulating layer IN2 may be formed on the first gate electrode pattern GA1, for example. In an embodiment, the second insulating layer IN2 may include or consist of the inorganic insulating material, for example. In an embodiment, the second insulating layer IN2 may be formed through the deposition process, for example. However, the disclosure is not limited thereto.

The second gate electrode pattern GA2 and the first capacitor electrode pattern CEP1 may be formed on the second insulating layer IN2. The second gate electrode pattern GA2 and the first capacitor electrode pattern CEP1 may be spaced apart from each other in the second direction DR2.

In an embodiment, each of the second gate electrode pattern GA2 and the first capacitor electrode pattern CEP1 may include or consist of the metal material, for example. In an embodiment, each of the second gate electrode pattern GA2 and the first capacitor electrode pattern CEP1 may be formed by the deposition process (e.g., the sputter process) and the photo process, for example. However, the disclosure is not limited thereto.

Referring to FIG. 14, in an embodiment, the etch stop pattern ES may be formed on the first capacitor electrode pattern CEP1, and the second active pattern ACT2 may be formed on the second gate electrode pattern GA2.

In an embodiment, the third insulating layer IN3 may be formed on the second gate electrode pattern GA2 and the first capacitor electrode pattern CEP1. In an embodiment, the third insulating layer IN3 may include or consist of the inorganic insulating material. In an embodiment, the third insulating layer IN3 may be formed by deposition process, for example. However, the disclosure is not limited thereto.

In an embodiment, the second active pattern ACT2 and the etch stop pattern ES may be formed on the third insulating layer IN3. In an embodiment, the etch stop pattern ES may be formed to overlap the first area A1 and the second area A2 of the first active pattern ACT1. The second active pattern ACT2 may be spaced apart from the etch stop pattern ES in the second direction DR2. The second active pattern ACT2 may include the third area A3, the fourth area A4, and the second channel area CH2 disposed between the third area A3 and the fourth area A4.

In an embodiment, the first active pattern ACT1 and the second active pattern ACT2 may include different materials from each other. As described above, the first active pattern ACT1 may include or consist of a silicon semiconductor. The second active pattern ACT2 may include or consist of an oxide semiconductor.

In an embodiment, the etch stop pattern ES and the second active pattern ACT2 may be formed simultaneously. In this case, the etch stop pattern ES and the second active pattern ACT2 may include a same oxide semiconductor.

In an embodiment, the second active pattern ACT2 and the etch stop pattern ES may include or consist of IGZO material. In an embodiment, the second active pattern ACT2 and the etch stop pattern ES may be formed by the deposition process (e.g., the sputtering process) and the photo process, for example. However, the disclosure is not limited thereto.

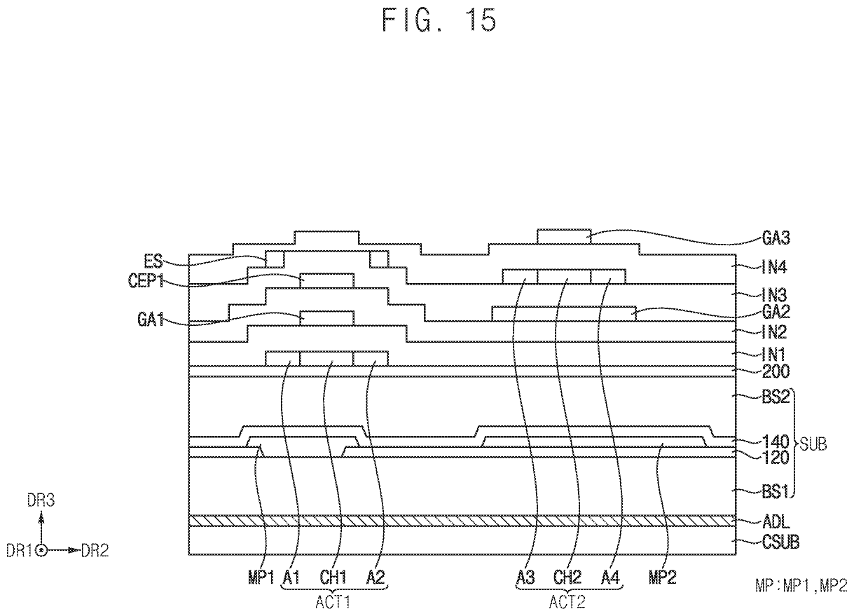

Referring to FIG. 15, the third gate electrode pattern GA3 may be formed on the second active pattern ACT2 and the etch stop pattern ES. The third gate electrode pattern GA3 may be formed to overlap a portion of the second active pattern ACT2.

In an embodiment, the fourth insulating layer IN4 may be formed on the second active pattern ACT2 and the etch stop pattern ES. In an embodiment, the fourth insulating layer IN4 may include or consist of the inorganic insulating material, for example. In an embodiment, the fourth insulating layer IN4 may be formed by deposition process, for example. However, the disclosure is not limited thereto.

The third gate electrode pattern GA3 may be formed on the fourth insulating layer IN4. In an embodiment, the third gate electrode pattern GA3 may include or consist of the metal material, for example. In an embodiment, the third gate electrode pattern GA3 may be formed by the deposition process (e.g., the sputtering process) and the photo process, for example. However, the invention is not limited thereto.

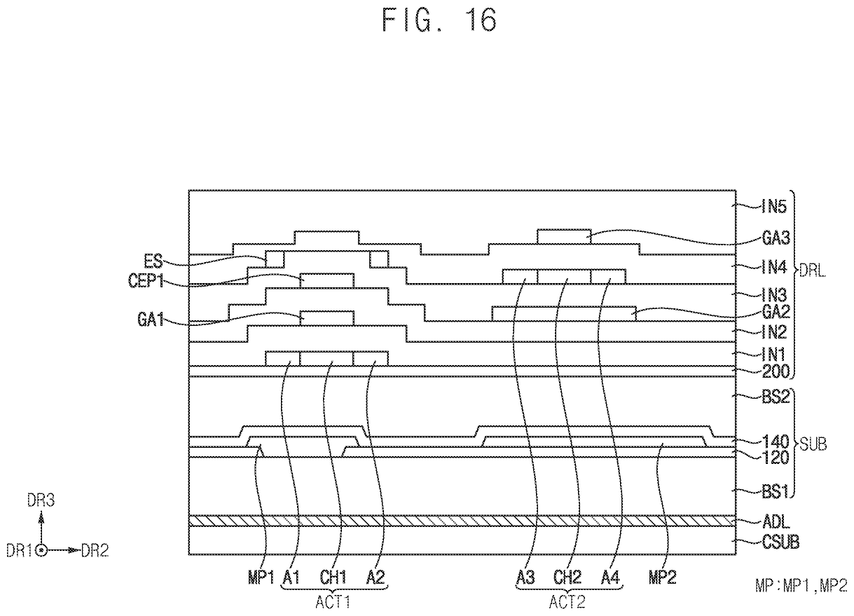

Referring to FIG. 16, in an embodiment, an inter-insulating layer covering the etch stop pattern ES may be formed. In an embodiment, the inter-insulating layer may refer to the fifth insulating layer IN5, for example.

In an embodiment, the fifth insulating layer IN5 may be formed on the third gate electrode pattern GA3, for example. In an embodiment, the fifth insulating layer IN5 may include or consist of the inorganic insulating material, for example. In an embodiment, the fifth insulating layer IN5 may be formed by the deposition process, for example. However, the disclosure is not limited thereto.

In an embodiment, the etch rate of the first insulating layer IN1, the etch rate of the second insulating layer IN2, the etch rate of the third insulating layer IN3, the etch rate of the fourth insulating layer IN4, and the etch rate of the fifth insulating layer IN5 may be less than the etch rate of an etch stop pattern (e.g., the etch stop pattern ES of FIG. 17).

In an embodiment, when the first to fifth insulating layers (IN1, IN2, IN3, IN4, and IN5) may include the inorganic material, the etch selectivity ratio between at least one of the first to fifth insulating layers IN1, IN2, IN3, IN4, and IN5 and the etch stop pattern may be about 1:15 or more.

In an embodiment, when the first to fifth insulating layers IN1, IN2, IN3, IN4, and IN5 may include the organic material, the etch selectivity ratio between at least one of the first to fifth insulating layers IN1, IN2, IN3, IN4, and IN5 and the etch stop pattern may be about 1:1000 or more.

As described above, when the etch selectivity between the insulating layer and the etch stop pattern is less than the above numerical range, a contact hole exposing a top surface of the metal pattern MP and a top surface of the first active pattern ACT1 may be difficult to simultaneously form.

Referring to FIGS. 17, 18, and 19, through the process of defining the first contact hole, the first hole OS1, the second hole OS2, the third hole OS3, and the fourth hole OS4, and the fifth hole OS5 may be formed. In an embodiment, the process of defining the first contact hole may be a dry etching process, for example.

As shown in FIG. 17, in an embodiment, the process of defining the first contact hole may begin by defining the first hole OS1 and the second hole OS2 together. The first hole OS1 and the second hole OS2 may penetrate the fourth insulating layer IN4 and the fifth insulating layer IN5.

The first hole OS1 may expose the etch stop pattern ES. The second hole OS2 may expose the inter-insulating layer. The first hole OS1 and the second hole OS2 may be defined together. In an embodiment, the inter-insulating layer may be the third insulating layer IN3, for example. However, the disclosure is not limited thereto.

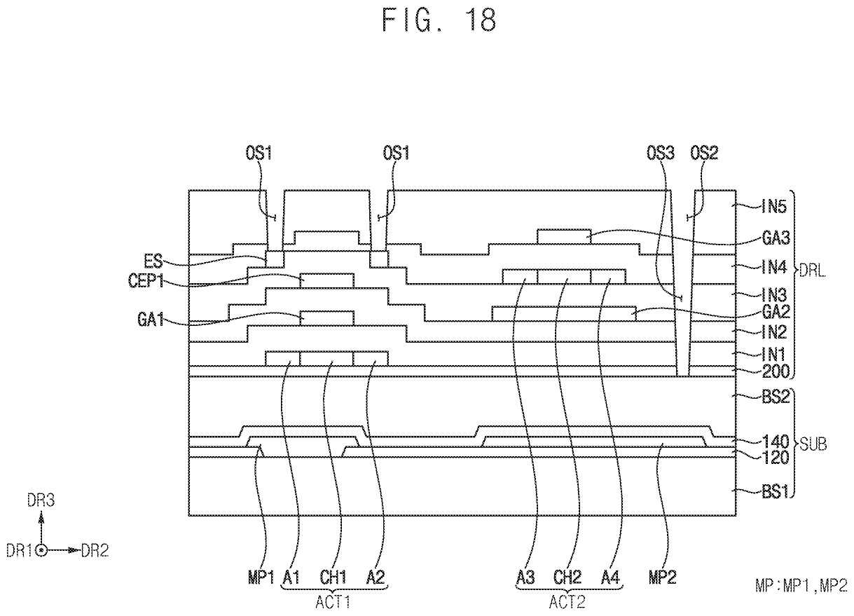

As shown in FIG. 18, in an embodiment, the third hole OS3 that is extended to the second hole OS2 and exposes a top surface of the substrate SUB may be defined. In an embodiment, the third hole OS3 may expose a top surface of the second base substrate BS2.

In an embodiment, the etch rate of the etch stop pattern ES is determined by the insulating layers disposed below the etch stop pattern ES (e.g., the first insulating layer IN1, the second insulating layer IN2, the third insulating layer IN3, fourth insulating layer IN4, and the fifth insulating layer IN5).

As the loss occurs in the etch stop pattern ES, the etch time of the etch stop pattern ES may be adjusted. In an embodiment, the etching time may be adjusted by adjusting an etch power, for example.

While a portion of the insulating layers are etched, the etch stop pattern ES may be preserved or only a relatively small amount may be etched. In an embodiment, the etch stop pattern ES may remain until a portion of the top surface of the second base substrate BS2 is exposed, for example.

As shown in FIG. 19, in an embodiment, the process of defining the first contact hole may be completed by defining the fourth hole OS4 and the fifth hole OS5.

The fourth hole OS4 may be extended to the first hole OS1 and may penetrate the etch stop pattern ES, the first insulating layer IN1, the second insulating layer IN2, and the third insulating layer IN3. Accordingly, the top surface of the first active pattern ACT1 may be exposed. During the process of defining the fourth hole OS4, etch stop pattern residue ESR may remain.

The fifth hole OS5 may be extended to the third hole OS3 and may penetrate the second base substrate BS2 the second buffer layer 140. Accordingly, the top surface of the metal pattern (e.g., the second metal pattern MP2) may be exposed.

In an embodiment, the fifth hole OS5 may be defined in a first portion PA1. The first portion PA1 may correspond to the display area DA of FIG. 2. In an embodiment, the fifth hole OS5 may be defined in a second portion PA2. The second portion PA2 may correspond to the non-display area NA of FIG. 2. Accordingly, the power voltage may be supplied through the pad (e.g., the pad disposed in the non-display area NA or through the line disposed in the fifth hole OS5. By receiving the power voltage from four directions, luminance deviation may be improved and power consumption may be improved.

In the process of defining the first contact hole, the first hole OS1, the second hole OS2, the third hole OS3, the fourth hole OS4, and the fifth hole OS5 may be defined together. Accordingly, the efficiency of the manufacturing process of the display device may be improved. In addition, after forming the substrate SUB, by defining the first hole OS1, the second hole OS2, the third hole OS3, the fourth hole OS4, and the fifth hole OS5 using one mask, manufacturing costs may be reduced.

Referring to FIGS. 19, 20, and 21, in an embodiment, the light-emitting device ED may be formed on the metal pattern connection electrode MCE. After forming the light-emitting device ED, the carrier substrate CSUB may be removed.

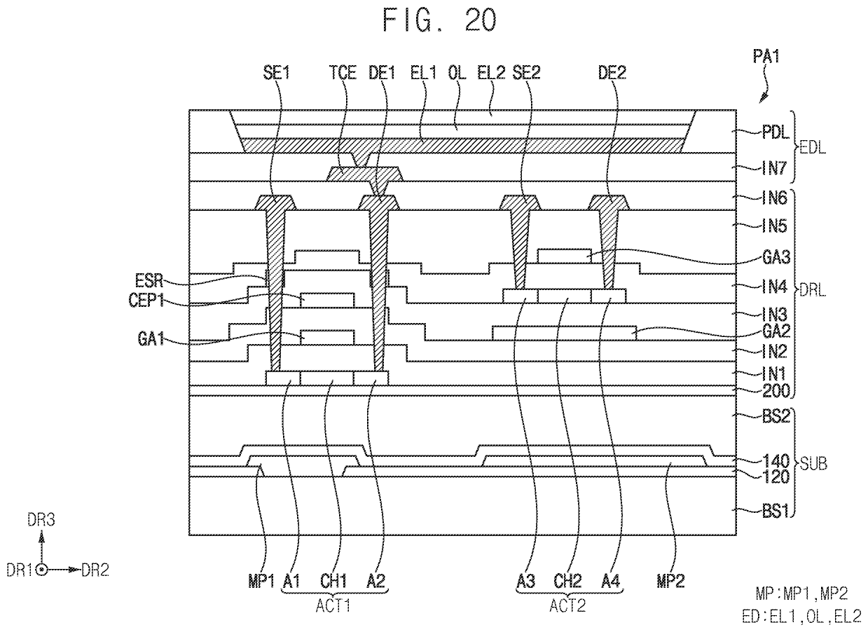

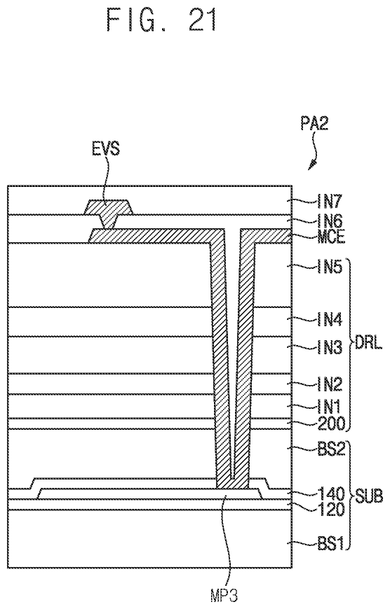

In an embodiment, FIG. 20 shows only up to the first portion PA1 of FIG. 19, and FIG. 21 shows only up to the second part PA2 of FIG. 19, for example. The first portion PA1 of FIG. 19 may correspond to the display area DA of FIG. 2, and the second portion PA2 of FIG. 20 may correspond to the non-display area NA of FIG. 2.

As shown in FIGS. 19 and 20, the first source electrode SE1 and the first drain electrode DE1 may be formed to fill the first hole OS1 and the fourth hole OS4.

In an embodiment, each of the first source electrode SE1 and the first drain electrode DE1 may include or consist of the metal material, for example. In an embodiment, each of the first source electrode SE1 and the first drain electrode DE1 may be formed by the deposition process (e.g., the sputter process) and the photo process, for example. However, the disclosure is not limited thereto.

As shown in FIG. 21, the metal pattern connection electrode MCE may be formed to fill the second hole OS2, the third hole OS3, and the fifth hole OS5.

In an embodiment, the metal pattern connection electrode MCE may include or consist of the metal material, for example. In an embodiment, the metal pattern connection electrode MCE may be formed by the deposition process (e.g., the sputtering process) and the photo process, for example. However, the disclosure is not limited thereto.

After the process of defining the first contact hole (e.g., the first hole OS1, the second hole OS2, the third hole OS3, the fourth hole OS4, and the fifth hole OS5), the secondary contact hole forming process may proceed. Through the secondary contact hole forming process, the second source electrode and the second drain electrode (e.g., the second source electrode SE2 and the second drain electrode of FIG. 20) may be connected to the second active pattern ACT2.

Referring back to FIG. 20, the first source electrode SE1, the first drain electrode DE1, the second source electrode SE2, the second drain electrode DE2, and the metal pattern connection electrode MCE. may be formed on the fifth insulating layer IN5. In an embodiment, the fifth insulating layer IN5 may include or consist of the inorganic insulating material, for example. In an embodiment, the fifth insulating layer IN5 may be formed by the deposition process, for example. However, the disclosure is not limited thereto.

The connection electrode TCE may be formed on the sixth insulating layer IN6. The connection electrode TCE may be connected to the first drain electrode DE1 (or the first source electrode SE1) through a contact hole penetrating the sixth insulating layer IN6. In an embodiment, the connection electrode TCE may include or consist of the metal material, for example. In an embodiment, the connection electrode TCE may be formed by the deposition process (e.g., the sputter process) and the photo process, for example. However, the disclosure is not limited thereto.

The seventh insulating layer IN7 may be formed on the connection electrode TCE. In an embodiment, the seventh insulating layer IN7 may include or consist of the inorganic insulating material, for example. In an embodiment, the seventh insulating layer IN7 may be formed by the deposition process, for example. However, the disclosure is not limited thereto.

In an embodiment, the first electrode EL1, the light-emitting material layer OL, and the second electrode EL2 may be sequentially formed on the seventh insulating layer IN7. Accordingly, the light-emitting device layer EDL including the light-emitting device ED may be formed.

The first electrode EL1 may be formed on the seventh insulating layer IN7. In an embodiment, the first electrode EL1 may include or consist of the metal material, for example. In an embodiment, the first electrode EL1 may be formed by the deposition process (e.g., the sputter process) and the photo process, for example. However, the disclosure is not limited thereto.

The pixel defining layer PDL may be formed on the first electrode EL1. The pixel defining layer PDL may define the pixel opening that exposes the portion of the top surface of the first electrode EL1.

The light-emitting material layer OL may be formed within the pixel opening defined by the pixel defining layer PDL. In an embodiment, the light-emitting material layer OL may be formed by an inkjet process, for example. However, the disclosure is not limited thereto. In an embodiment, the light-emitting material layer OL may be formed by various processes such as a patterning process.

The second electrode EL2 may be formed on the light-emitting material layer OL. In an embodiment, the second electrode EL2 may include or consist of the metal material, for example. In an embodiment, the second electrode EL2 may be formed by the deposition process (e.g., the sputter process) and the photo process, for example. However, the disclosure is not limited thereto.

In an embodiment, after forming the light-emitting device layer EDL, the carrier substrate CSUB may be removed. In an embodiment, the carrier substrate CSUB may be separated from the substrate SUB by a laser lift off (“LLO”) process, for example.

In an embodiment, physical properties of the auxiliary layer ADL may be changed by the laser, for example. Due to the change in physical properties, the auxiliary layer ADL may easily separate the carrier substrate CSUB from the substrate SUB. However, the disclosure is not limited thereto.

The manufacturing method of the display device in embodiments of the disclosure and the display device manufactured thereby may be applied to computers, laptops, mobile phones, smartphones, smart pads, portable media players (“PMPs”), personal digital assistants (“PDAs”), MP3 players, or the like.

The disclosure should not be construed as being limited to the embodiments set forth herein. Rather, these embodiments are provided so that this disclosure will be thorough and complete and will fully convey the concept of the invention to those skilled in the art. While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A manufacturing method of a display device, the method comprising:
preparing a substrate which includes a metal pattern and in which a display area and a non-display area are defined;
forming a first active pattern disposed on the substrate and including a first area, a second area, and a first channel area disposed between the first area and the second area;
forming a first gate electrode pattern overlapping the first channel area on the first active pattern;
forming a second active pattern on the first gate electrode pattern;
forming an etch stop pattern in a same layer as the second active pattern and overlapping the first area and the second area of the first active pattern;
forming an inter-insulating layer covering the etch stop pattern;
defining a first hole exposing the etch stop pattern and a second hole exposing the inter-insulating layer;
defining a third hole extended to the second hole and exposing a top surface of the substrate;
defining a fourth hole extended to the first hole and penetrating the etch stop pattern and a fifth hole extended to the third hole and exposing the metal pattern;
forming a metal pattern connection electrode disposed on the metal pattern and connected to the metal pattern through the fifth hole; and
forming a light-emitting device on the metal pattern connection electrode.

2. The method of claim 1, wherein the forming the substrate comprising:
forming a first base substrate on a carrier substrate;
forming the metal pattern on the first base substrate; and
forming a second base substrate on the first base substrate and the metal pattern.

3. The method of claim 2, wherein the third hole exposes a top surface of the second base substrate.

4. The method of claim 2, wherein the first base substrate and the second base substrate include plastic with flexible characteristics.

5. The method of claim 4, wherein the first base substrate and the second base substrate include polyimide.

6. The method of claim 2, further comprising:
removing the carrier substrate after the forming the light-emitting device.

7. The method of claim 1, further comprising:
forming a first insulating layer covering the first active pattern after the forming the first active pattern; and
forming a second insulating layer covering the first gate electrode pattern after the forming the first gate electrode pattern.

8. The method of claim 7, wherein an etch rate of the first insulating layer, an etch rate of the second insulating layer, and an etch rate of the inter-insulating layer are smaller than an etch rate of the etch stop pattern.

9. The method of claim 8, wherein when each of the first insulating layer, the second insulating layer, and the inter-insulating layer includes an inorganic material, an etch selectivity between at least one of the first insulating layer, the second insulating layer and the inter-insulating layer including the inorganic material and the etch stop pattern is about 1:15 or more.

10. The method of claim 8, wherein when each of the first insulating layer, the second insulating layer, and the inter-insulating layer includes an organic material, an etch selectivity between at least one of the first insulating layer, the second insulating layer and the inter-insulating layer including the organic material and the etch stop pattern is about 1:1000 or more.

11. The method of claim 1, wherein the first active pattern and the second active pattern include different materials from each other.

12. The method of claim 1, wherein the first active pattern includes a silicon semiconductor.

13. The method of claim 1, wherein the etch stop pattern and the second active pattern are formed simultaneously.

14. The method of claim 13, wherein the etch stop pattern and the second active pattern includes a same oxide semiconductor.

15. The method of claim 14, wherein the etch stop pattern and the second active pattern includes indium-gallium-zinc-oxide (“IGZO”).

16. The method of claim 1, wherein the fifth hole is defining in the display area.

17. The method of claim 1, wherein the fifth hole is defining in the non-display area.
